(19) United States
(12) Patent Application Publication
(10) Pub. No.: US 2025/0228081 A1
(43) Pub. Date: Jul. 10, 2025

(54) ELECTROSTATIC SHIELDING LAYER, DISPLAY DEVICE HAVING THE SAME, AND ELECTRONIC DEVICE INCLUDING THE SAME

(71) Applicant: Samsung Display Co., LTD., Yongin-si (KR)

(72) Inventors: DAE-WON LEE, Yongin-si (KR); SUNBEOM KWON, Yongin-si (KR); CHUNGI YOU, Yongin-si (KR)

(21) Appl. No.: 18/982,048

(22) Filed: Dec. 16, 2024

(30) Foreign Application Priority Data
Jan. 5, 2024 (KR) 10-2024-0002452

(51) Int. Cl. H10K 59/126; H10K 59/80; H10K 102/00

(52) U.S. Cl. CPC H10K 59/126; H10K 59/873; H10K 2102/351

(57) ABSTRACT

A display device includes a silicon substrate including a display area including a light emitting element, and a pixel circuit portion which is inside the silicon substrate and connected to the light emitting element, and a non-display area which is adjacent to the display area. The non-display area includes a driving circuit portion which is inside the silicon substrate and through which an electrical signal is provided to the display area, and an electrostatic shielding layer covering the driving circuit portion.

This application claims priority to Korean Patent Application No. 10-2024-0002452 filed on Jan. 5, 2024 and all the benefits accruing therefrom under 35 U.S.C. § 119, the entire contents of which are hereby incorporated by reference.

### BACKGROUND

### 1. Field

Embodiments provide generally to a display device. More particularly, embodiments relate to a display device which provides visual information.

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

A display device using a high-resolution micro OLED has been developed. The high-resolution micro OLED may be OLEDos (organic light emitting diodes on silicon) formed (or provided) using a silicon wafer-based semiconductor process. For example, the display device using the high-resolution micro OLED may be a head mounted display (HMD) which is a glasses-type monitor device for virtual reality (VR) or augmented reality (AR) which is worn in the form of glasses, a helmet, and the like, and focuses on being disposed a close distance in front of the user's eyes. The head-mounted display may provide an image displayed on a display device, to the user's eyes, through a lens.

### SUMMARY

Embodiments provide a display device in which defects caused by electrostatic discharge are improved.

A display device according to embodiments of the present disclosure includes a silicon substrate including a display area and a non-display area located around the display area, a pixel circuit portion disposed inside the silicon substrate in the display area, a driving circuit portion disposed inside the silicon substrate in the non-display area, and a shielding layer disposed on the driving circuit portion and covering the driving circuit portion in a plan view.

In an embodiment, the shielding layer may include a metal material.

In an embodiment, the display device may further include a pixel electrode disposed on the silicon substrate and electrically connected to the pixel circuit portion, a light emitting layer disposed on the pixel electrode, and a common electrode disposed on the light emitting layer.

In an embodiment, the shielding layer may include a same material as the common electrode.

In an embodiment, the shielding layer may be spaced apart from the common electrode.

In an embodiment, the common electrode may continuously extend from the display area to at least a part of the non-display area, and the shielding layer may include a part of the common electrode overlapping the non-display area.

In an embodiment, the shielding layer may include a same material as the pixel electrode.

In an embodiment, the shielding layer may be spaced apart from the pixel electrode.

In an embodiment, the shielding layer may include an inorganic material.

In an embodiment, the shielding layer may include glass.

In an embodiment, the display device may further include a light emitting element disposed in the display area on the silicon substrate, an encapsulation layer disposed on the light emitting element and including an inorganic layer and an organic layer, and an encapsulation substrate including glass.

In an embodiment, the shielding layer may include a same material as the encapsulation layer.

In an embodiment, the shielding layer may include a same material as the encapsulation substrate.

In an embodiment, the display device may further include a dummy pattern disposed inside the silicon substrate in the non-display area and a guard ring pattern disposed inside the silicon substrate and adjacent to the dummy pattern in the non-display area.

In an embodiment, the shielding layer may be connected to the dummy pattern or the guard ring pattern.

In an embodiment, the shielding layer may have a planar shape defined by a plurality of openings spaced apart from each other.

A display device according to embodiments of the present disclosure includes a silicon substrate including: a display area and a non-display area including a pad area spaced apart from one side of the display area in a first direction and located around the display area, a pixel circuit portion disposed inside the silicon substrate in the display area, a driving circuit portion disposed inside the silicon substrate in an area excluding the pad area of the non-display area, a plurality of signal pads arranged in the pad area of the silicon substrate along a second direction crossing the first direction, a circuit board electrically connected to the signal pads, a timing controller disposed directly on the circuit board, and a shielding layer disposed on the driving circuit portion and covering the driving circuit portion in a plan view.

In an embodiment, the display device may further include a pixel electrode disposed on the silicon substrate and electrically connected to the pixel circuit portion, a light emitting layer disposed on the pixel electrode, and a common electrode disposed on the light emitting layer. The shielding layer may include a same material as the pixel electrode or the common electrode.

In an embodiment, the display device may further include a light emitting element disposed in the display area on the silicon substrate, an encapsulation layer disposed on the light emitting element and including at least one inorganic layer and at least one organic layer, and an encapsulation substrate including glass. The shielding layer may include a same material as the encapsulation layer or the encapsulation substrate.

In an embodiment, the display device may further include a dummy pattern disposed inside the silicon substrate in the non-display area and a guard ring pattern disposed inside the silicon substrate and located between the dummy pattern and the signal pads in a plan view in the pad area. The shielding layer may be connected to the dummy pattern or the guard ring pattern.

An electronic device according to embodiments of the present disclosure includes a display device and a processor which controls the display device, the display device includes a silicon substrate including: a display area including a light emitting element, and a pixel circuit portion which is inside the silicon substrate and connected to the light emitting element, and a non-display area which is adjacent to the display area, the non-display area including: a driving circuit portion which is inside the silicon substrate and through which an electrical signal is provided to the display area and an electrostatic shielding layer covering the driving circuit portion.

A display device according to embodiments of the present disclosure may include a base substrate including a silicon wafer, a driving circuit portion disposed inside the base substrate in a non-display area, and a shield layer disposed on the driving circuit portion and covering an entire driving circuit in a plan view. Accordingly, the shielding layer may block or prevent external electrostatic discharge from flowing into the driving circuit portion. In this case, defects in the display device due to electrostatic discharge may be prevented.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a cross-sectional view taken along line I-I′ of FIG. 1.

FIG. 3 is a cross-sectional view illustrating an example of a cross-section taken along line II-II′ in FIG. 1.

FIG. 4 is a plan view illustrating a driving circuit and a shielding layer of FIG. 3.

FIGS. 5, 6, and 7 are plan views illustrating examples of the planar shape of a shielding layer of FIG. 3.

FIG. 8 is a cross-sectional view illustrating an example of a cross-section taken along line II-II′ in FIG. 1.

FIG. 9 is a cross-sectional view illustrating an example of a cross-section taken along line II-II′ in FIG. 1.

FIG. 10 is a cross-sectional view illustrating an example of a cross-section taken along line II-II′ in FIG. 1.

FIG. 11 is a cross-sectional view illustrating an example of a cross-section taken along line II-II′ in FIG. 1.

FIG. 12 is a block diagram illustrating an electronic device according to an embodiment of the present disclosure.

### DETAILED DESCRIPTION

Hereinafter, a display device DD according to embodiments of the present disclosure will be explained in detail with reference to the accompanying drawings. The same reference numerals are used for the same components in the drawings, and redundant descriptions of the same components will be omitted.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. Within the Figures and the text of the disclosure, a reference number indicating a singular form of an element may also be used to reference a plurality of the singular element. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

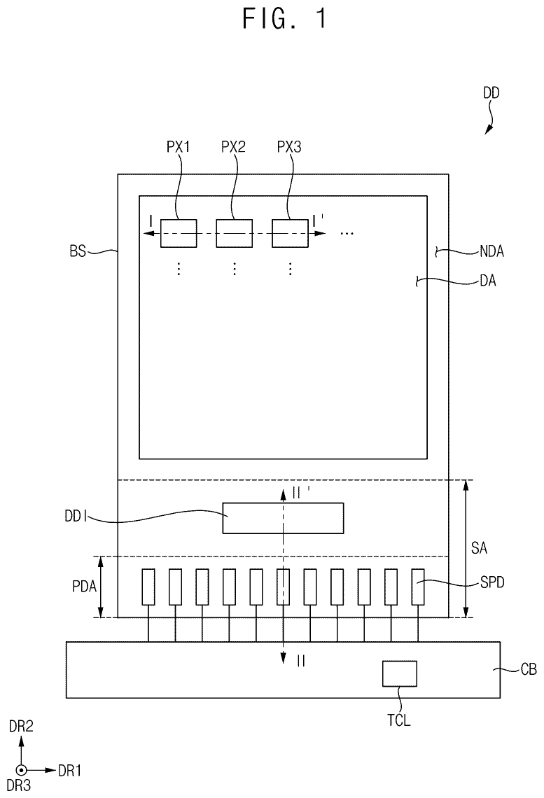

FIG. 1 is a plan view illustrating a display device DD according to an embodiment of the present disclosure.

Referring to FIG. 1, a display device DD according to an embodiment of the present disclosure may include a base substrate BS, a driving circuit portion DDI, a signal pad SPD provided in plural including a plurality of signal pads SPD, a circuit board CB, and a timing controller TCL.

The base substrate BS may include a display area DA and a non-display area NDA.

The display area DA may be an area (e.g., a planar area) at which an image is displayed, by generating light or adjusting the transmittance of light provided from an external light source. The non-display area NDA may be an area which does not display images. The non-display area NDA may be located adjacent to the display area DA, such as being extended along or around the display area DA. For example, the non-display area NDA may entirely surround the display area DA.

The display area DA may include a pixel area provided in plural including a plurality of pixel areas. The pixel areas may be arranged in a matrix form along a first direction DR1 and a second direction DR2 which crosses the first direction DR1. For example, the pixel areas may include a first pixel area PX1, a second pixel area PX2, and a third pixel area PX3.

Each of the first pixel area PX1, the second pixel area PX2, and the third pixel area PX3 may denote an area where light emitted from a light emitting element is emitted to the outside of the display device DD. For example, the first pixel area PX1 may emit a first light, the second pixel area PX2 may emit a second light, and the third pixel area PX3 may emit a third light. In an embodiment, the first light may be red light, the second light may be green light, and the third light may be blue light. However, the present disclosure is not limited thereto. For example, the first, second, and third pixel areas PX1, PX2, and PX3 may be combined to emit yellow, cyan, and magenta lights.

The first, second, and third pixel areas PX1, PX2, and PX3 may emit light of four or more colors. For example, the first, second, and third pixel areas PX1, PX2, and PX3 may be combined to emit at least one of yellow, cyan, and magenta lights in addition to red, green, and blue lights. In addition, the first, second, and third pixel areas PX1, PX2, and PX3 may be combined to emit more white light.

Each of the first pixel area PX1, the second pixel area PX2, and the third pixel area PX3 may have a triangular planar shape, a square planar shape, a circular planar shape, an oval planar shape, or the like, in the plan view. In an embodiment, each of the first pixel area PX1, the second pixel area PX2, and the third pixel area PX3 may have a rectangular planar shape. However, the embodiments of the present disclosure are not limited, and each of the first pixel area PX1, the second pixel area PX2, and the third pixel area PX3 may have a different planar shape from each other.

The non-display area NDA may include a sub-area SA. The sub-area SA may be positioned spaced apart from one side of the display area DA in a direction opposite to the second direction DR2. For example, the sub-area SA may have a shape extending in the first direction DR1.

The sub-area SA may include a pad area PDA. The pad area PDA may be located spaced apart from one side of the display area DA in a direction opposite to the second direction DR2. For example, the pad area PDA may have a shape extending in the first direction DR1. That is, the pad area PDA may be elongated or have a major dimension in the first direction DR1 to be considered “extended” in the first direction DR1.

A driver may be disposed in the non-display area NDA. The driver may provide signals (e.g., electrical signals) and/or voltages to the pixel areas. For example, the driver may include a data driver, a scan driver, a light emitting driver, and the like.

A plurality of lines (e.g., signal lines, conductive lines, etc.) may be disposed in a portion of the non-display area NDA which is outside of the pad area PDA and the sub-area SA, and the plurality of signal pads SPD may be disposed in the pad area PDA. The lines may electrically connect signal pads SPD and the pixel areas to each other. For example, the lines may include data voltage lines, scan signal lines, light emitting control signal lines, power voltage lines, and the like.

The signal pads SPD may be arranged to be spaced apart from each other along the first direction DR1. For example, each of the signal pads SPD may include metal, alloy, metal nitride, conductive metal oxide, transparent conductive material, and the like. These can be used alone or in combination with each other.

The driving circuit portion DDI may be disposed in the sub-area SA. Specifically, the driving circuit portion DDI may be disposed in an area of the sub-area SA excluding the pad area PDA. In an embodiment, the driving circuit portion DDI may be disposed inside the base substrate BS. That is, the driving circuit portion DDI may be mounted as an embedded type in the sub-area SA. Here, the driving circuit portion DDI may be within a thickness of the base substrate BS.

The driving circuit portion DDI may convert a digital data signal among the driving signals provided through the circuit board CB into an analog data signal as a converted data signal, and provide the converted data signal to the pixel areas. For example, the driving circuit portion DDI (e.g., driving circuit) may be a data driving portion (e.g., a data driver). However, embodiments of the present disclosure are not limited thereto.

The circuit board CB may be electrically connected to the signal pads SPD at one end of the circuit board CB (e.g., a first side or a first end). In addition, the circuit board CB may be electrically connected to an external device (not shown) at the other end of the circuit board CB (e.g., a second side or a second end). The circuit board CB may receive driving signals (e.g., data voltage, scan signal, light emitting control signal, power voltage, and the like) generated from the external device. For example, the circuit board CB may include a flexible printed circuit board (FPCB) or a printed circuit board (PCB). The external device may be an electronic component such as a circuit board, without being limited thereto.

The timing controller TCL may be disposed on the circuit board CB. Specifically, the timing controller TCL may be placed directly on the circuit board CB. The timing controller TCL may generate electrical signals such as a scan control signal for controlling the scan driver, a data control signal for controlling the data driver, and a light emitting control signal for controlling the light emitting driver. In addition, the timing controller TCL may generate a digital data signal and provide the digital data signal to the data driver.

In this specification, a plane may be defined as the first direction DR1 and the second direction DR2 which crosses the first direction DR1. For example, the first direction DR1 may be perpendicular to the second direction DR2. In addition, a third direction DR3 may intersect the plane such as being perpendicular to the plane. A thickness of the display device DD and various components or layers thereof may be defined along the third direction DR3 (e.g., a thickness direction)

The display device DD according to an embodiment of the present disclosure may include an organic light emitting display device, a liquid crystal display device, an organic light emitting diode on silicon substrate (OLEDos), a liquid crystal on silicon substrate (LCos), or a light emitting diode on silicon substrate (LEDos). In an embodiment, the display device DD may be a display device such as OLEDos. Hereinafter, it will be explained by taking as an example that the display device DD is a display device such as OLEDos.

For example, if the display device DD is a display device DD such as OLEDos, the display device DD may be a head mounted display, which is a glasses-type monitor device for virtual reality or augmented reality which is worn in the form of glasses, a helmet, and the like and focuses on a close distance in front of a body part such as the user's eyes. However, embodiments of the present disclosure are not limited to this, and the display device DD may configure various displays.

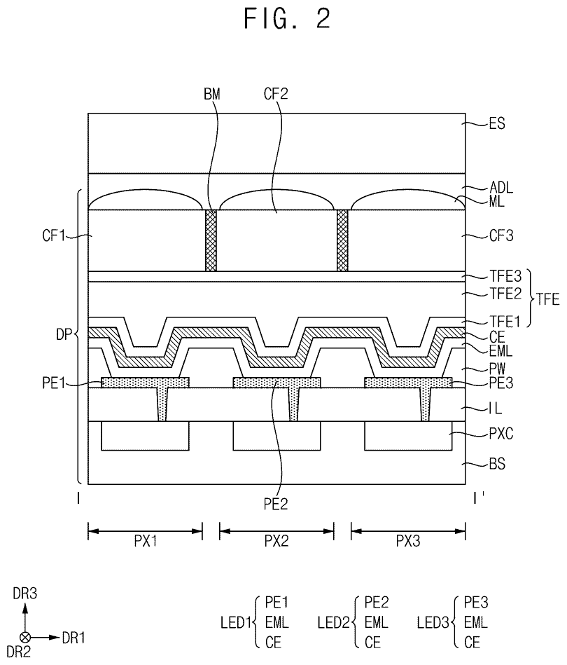

FIG. 2 is a cross-sectional view taken along line I-I′ of FIG. 1. For example, FIG. 2 is a cross-sectional view illustrating the first, second, and third pixel areas PX1, PX2, and PX3 included in the display area DA of FIG. 1.

Referring to FIGS. 1 and 2, the display device DD according to an embodiment of the present disclosure may include a display panel DP and an encapsulation substrate ES which is disposed on the display panel DP. The display panel DP may include a base substrate BS, a plurality of pixel circuit portions PXC within a pixel circuit layer, an insulating layer IL, first, second, and third light emitting elements LED1, LED2, and LED3 within a light emitting element layer connected to the pixel circuit layer, a partition wall PW within a pixel defining layer, an encapsulation layer TFE, first, second, and third color filter layers CF1, CF2, and CF3 together with a light blocking layer BM in a color filter layer, and a lens layer.

Here, the first light emitting element LED1 may include a first pixel electrode PE1, a light emitting layer EML and a common electrode CE, the second light emitting element LED2 may include a second pixel electrode PE2, the light emitting layer EML and the common electrode CE, and the third light emitting element LED3 may include a third pixel electrode PE3, the light emitting layer EML and the common electrode CE.

In an embodiment, the base substrate BS may include a silicon wafer formed (or provided) using a semiconductor process. The base substrate BS may be a support member or base layer for supporting other components of the display device DD. In this specification, the base substrate BS may be referred to as a silicon substrate.

The plurality of pixel circuit portions PXC may be disposed inside the base substrate BS. The pixel circuit portions PXC may overlap the first pixel area PX1, the second pixel area PX2, and the third pixel area PX3, respectively, along the thickness direction. As being ‘inside’ the base substrate BS, where each of the pixel circuit portions PXC and the base substrate SB has a thickness along the third direction DR3, an entirety of the thickness of the pixel circuit portions PXC is within the thickness of the base substrate BS. Referring to FIG. 2, for example, an upper surface of the pixel circuit portions PXC may be substantially coplanar with an upper surface of base substrate BS, without being limited thereto.

Each of the pixel circuit portions PXC may include various driving elements, lines, and the like for driving the first, second, and third light emitting elements LED1, LED2, and LED3. For example, each of the pixel circuit portions PXC may include various components such as a transistor, a storage capacitor, a scan signal line, a data signal line, and the like. However, embodiments of the present disclosure are not limited thereto. In an embodiment, the non-display area NDA may include a driving circuit portion PXC which is inside the silicon substrate and through which an electrical signal is provided to the display area DA.

The insulating layer IL may be disposed on the pixel circuit portions PXC. The insulating layer IL may reduce or effectively prevent undesirable contact (e.g., an electrical short circuit) between the first, second, and third pixel electrodes PE1, PE2, and PE3, and the pixel circuit portions PXC, respectively. The insulating layer IL may include organic materials and/or inorganic materials. For example, the insulating layer IL may include an inorganic material such as silicon oxide (SiOₓ), silicon nitride (SiNₓ), silicon oxynitride (SiOₓN_{y}), and the like. These can be used alone or in combination with each other.

The first, second, and third pixel electrodes PE1, PE2, and PE3 may be disposed on the insulating layer IL. The first pixel electrode PE1 may overlap the first pixel area PX1, the second pixel electrode PE2 may overlap the second pixel area PX2, and the third pixel electrode PE3 may overlap the third pixel area PX3. The first pixel electrode PE1 may be electrically connected to the pixel circuit portion PXC through a contact hole penetrating the insulating layer IL in the first pixel area PX1, the second pixel electrode PE2 may be electrically connected to the pixel circuit portion PXC through a contact hole penetrating the insulating layer IL in the second pixel area PX2, and the third pixel electrode PE3 may be electrically connected to the pixel circuit portion PXC through a contact hole penetrating the insulating layer IL in the third pixel area PX3. A solid portion of the insulating layer IL may define the various contact holes.

Each of the first, second, and third pixel electrodes PE1, PE2, and PE3 may include metal, alloy, metal nitride, conductive metal oxide, transparent conductive material, and the like. The first, second, and third pixel electrodes PE1, PE2, and PE3 may include the same material as each other and be formed through the same process, such as to be in a same layer as each other. For example, each of the first, second, and third pixel electrodes PE1, PE2, and PE3 may have a multilayer structure including ITO/Ag/ITO. However, embodiments of the present disclosure are not limited thereto. Each of the first, second, and third pixel electrodes PE1, PE2, and PE3 may be an anode electrode. Each of the first, second, and third pixel electrodes PE1, PE2, and PE3 may be a reflective electrode. However, embodiments of the present disclosure are not limited thereto. As being in a same layer, elements may be formed in a same process and/or include a same material as each other, elements may be respective portions or patterns of a same material layer, elements may be on a same layer by forming an interface with a same underlying or overlying layer, etc., without being limited thereto.

The partition wall PW may be disposed on the insulating layer IL. The partition wall PW may cover the edges of each of the first, second, and third pixel electrodes PE1, PE2, and PE3. In addition, the partition wall PW may define pixel openings which expose at least a part of an upper surface of each of the first, second, and third pixel electrodes PE1, PE2, and PE3, to outside of the partition wall PW. For example, the partition wall PW may include an inorganic material such as silicon oxide, silicon nitride, silicon oxynitride, and the like. These can be used alone or in combination with each other. In an embodiment, the partition wall PW may have a multi-layer structure, but embodiments of the present disclosure are not limited thereto.

The light emitting layer EML may be disposed on the first, second, and third pixel electrodes PE1, PE2, and PE3 and the partition wall PW. The light emitting layer EML may be a common layer commonly formed in the first, second, and third pixel areas PX1, PX2, and PX3. That is, the light emitting layer EML may continuously extend throughout the display area DA, through the first, second, and third pixel areas PX1, PX2, and PX3. For example, the light emitting layer EML may include a hole injection layer, a hole transport layer, an organic light emitting layer, an electron injection layer, an electron transport layer, and the like. In an embodiment, the organic light emitting layer may include a light emitting material which emits white light. For example, the white light may be a mixture of blue light, green light, and red light. Alternatively, the white light may be a mixture of blue light and yellow light.

However, the embodiments of the present disclosure are not limited to this, and the light emitting layer EML may include a first light emitting layer as a discrete pattern overlapping the first pixel area PX1 and including a light emitting material which emits red light, a second light emitting layer as a discrete pattern overlapping the second pixel area PX2 and including a light emitting material which emits green light, and a third light emitting layer as a discrete pattern overlapping the third pixel area PX3 and including a light emitting material which emits blue light. In this case, the first, second, and third light emitting layers may be separated from each other in a direction along the base substrate BS (e.g., discrete patterns), and the first, second, and third color filter layers CF1, CF2, and CF3 and the light blocking layer BM may be omitted.

The common electrode CE may be disposed on the light emitting layer EML. The common electrode CE may be a common layer commonly formed in the first, second, and third pixel areas PX1, PX2, and PX3. That is, the common electrode CE may continuously extend throughout the display area DA, through the first, second, and third pixel areas PX1, PX2, and PX3. For example, the common electrode CE may include metal, alloy, metal nitride, conductive metal oxide, transparent conductive material, and the like. These can be used alone or in combination with each other. The common electrode CE may be a cathode electrode. The common electrode CE may be a transmissive or semi-transmissive electrode.

Accordingly, the first pixel electrode PE1, the light emitting layer EML, and the common electrode CE may together form the first light emitting element LED1 in the first pixel area PX1, the second pixel electrode PE2, the light emitting layer EML, and the common electrode CE may together form the second light emitting element LED2 in the second pixel area PX2, and the third pixel electrode PE3, the light emitting layer EML, and the common electrode CE may together form the third light emitting element LED3 in the third pixel area PX3.

The encapsulation layer TFE may be disposed on the common electrode CE. The encapsulation layer TFE may continuously extend throughout the display area DA, through the first, second, and third pixel areas PX1, PX2, and PX3. The encapsulation layer TFE may prevent impurities, moisture, and the like from penetrating into the first, second, and third light emitting elements LED1, LED2, and LED3 from the outside.

The encapsulation layer TFE may include at least one inorganic layer and at least one organic layer. For example, the encapsulation layer TFE may include a first inorganic encapsulation layer TFE1, an organic encapsulation layer TFE2 disposed on the first inorganic encapsulation layer TFE1, and a second inorganic encapsulation layer TFE3 disposed on the organic encapsulation layer TFE2. The organic encapsulation layer TFE2 may have a substantially flat upper surface.

For example, the first and third inorganic encapsulation layers TFE1 and TFE3 may include silicon oxide, silicon nitride, silicon oxynitride, and the like. These can be used alone or in combination with each other. The organic encapsulation layer TFE2 may include a cured polymer such as polyacrylate.

The first, second, and third color filter layers CF1, CF2, and CF3 as patterns of the color filter layer may be disposed on the encapsulation layer TFE. The first color filter layer CF1 may overlap the first pixel area PX1, the second color filter layer CF2 may overlap the second pixel area PX2, and the third color filter layer CF3 may overlap the third pixel area PX3. Each of the first, second, and third color filter layers CF1, CF2, and CF3 may selectively transmit only light of a specific wavelength and absorb light of the remaining wavelengths. For example, red light may be transmitted through the first color filter layer CF1, green light may be transmitted through the second color filter layer CF2, and blue light may be transmitted through the third color filter layer CF3. Accordingly, the first pixel area PX1 may emit red light, the second pixel area PX2 may emit green light, and the third pixel area PX3 may emit blue light. However, embodiments of the present disclosure are not limited thereto.

The light blocking layer BM of the color filter layer may be disposed on the encapsulation layer TFE. The light blocking layer BM may be disposed respectively between the first, second, and third color filter layers CF1, CF2, and CF3. That is, the light blocking layer BM may not overlap the first, second, and third pixel areas PX1, PX2, and PX3. The light blocking layer BM may block light incident on the light blocking layer BM. Accordingly, the light blocking layer BM may prevent color mixing between the first, second, and third pixel areas PX1, PX2, and PX3. For example, the light blocking layer BM may include an organic material and/or an inorganic material containing black pigment, black dye, and the like.

The lens layer may be disposed on the first, second, and third color filter layers CF1, CF2, and CF3 and the light blocking layer BM. The lens layer may include a plurality of micro lenses ML. The micro lenses ML may improve light extraction efficiency. The micro lenses ML may overlap the first, second, and third pixel areas PX1, PX2, and PX3, respectively. The micro lenses ML may each be a discrete lens or lens pattern. The micro lenses ML may have a predetermined refractive index with respect to visible light. For example, the micro lenses ML may have a refractive index of about 1.5 or more to about 1.7 or less with respect to visible light. However, embodiments of the present disclosure are not limited thereto. For example, each of the micro lenses ML may have a convex cross-sectional shape curved in a direction away from the base substrate BS.

The encapsulation substrate ES may be disposed on the lens layer. The encapsulation substrate ES may be attached to the display panel DP through an adhesive layer ADL. The encapsulation substrate ES may protect the display panel DP from moisture penetration or gas inflow. The encapsulation substrate ES may include a transparent insulating substrate. For example, the encapsulation substrate ES may include glass. For example, the adhesive layer ADL may include an optical clear adhesive (OCA), a pressure sensitive adhesive (PSA), a photocurable resin, a thermosetting resin, or the like.

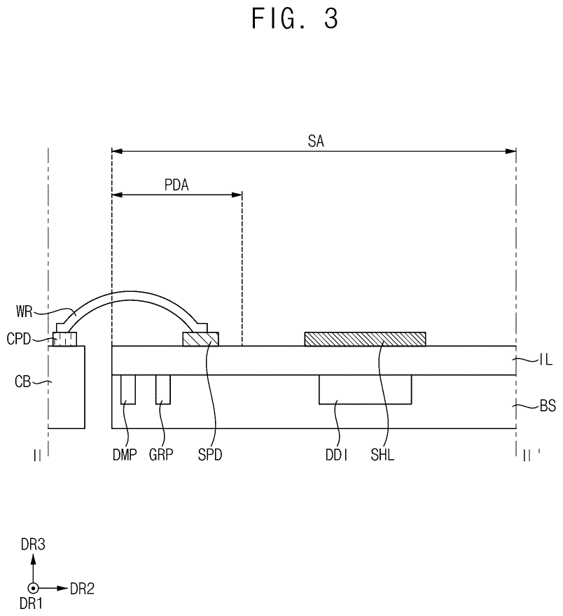

FIG. 3 is a cross-sectional view illustrating an example of a cross-section taken along line II-II′ in FIG. 1.

Referring to FIG. 3, the signal pads SPD of the display panel DP may be disposed in the pad area PDA, on the insulating layer IL. As described above, the circuit board CB may be electrically connected to the display panel DP, at the signal pads SPD. Specifically, pad electrodes CPD of the circuit board CB and the signal pads SPD of the display panel DP may be electrically connected to each other through a wire WR. In other words, the pad electrodes CPD, the wires WR, and the signal pads SPD may be connected to each other in a one-to-one correspondence.

In an embodiment, the display device DD may further include a shielding layer SHL disposed on the insulating layer IL and covering the driving circuit portion DDI in a plan view (e.g., a view along the third direction DR3). That is, the shielding layer SHL may be disposed to cover an entirety of the driving circuit portion DDI. In other words, the shielding layer SHL may be disposed to overlap the driving circuit portion DDI in the plan view. Accordingly, the shielding layer SHL may block or prevent external electrostatic discharge (ESD) from flowing into the driving circuit portion DDI. The shielding layer SHL may be disposed on a first surface (e.g., an upper surface) of the insulating layer IL, while the driving circuit portion DDI is disposed on a second surface (e.g. a lower surface) which is opposite to the first surface.

For example, the shielding layer SHL may include a metal material. In an embodiment, the shielding layer SHL may include the same material as the common electrode CE of FIG. 2. That is, the shielding layer SHL may be formed through the same process as the common electrode CE of FIG. 2, such as to be in a same layer as the common electrode CE. However, embodiments of the present disclosure are not limited to this, and the shielding layer SHL may include other materials. A detailed description of this will be provided later.

In an embodiment, when the shielding layer SHL is formed through the same process as the common electrode CE of FIG. 2, the shielding layer SHL may be spaced apart from the common electrode CE of FIG. 2, in a direction along the insulating layer IL, as illustrated by the shielding layer SHL spaced apart from the (right) broken line indicating the sub-area SA. That is, the shielding layer SHL may not be connected to the common electrode CE of FIG. 2, so as to be electrically disconnected or insulated from the common electrode CE. However, embodiments of the present disclosure are not limited thereto. A detailed description of this will be provided later.

The display device DD may further include a dummy pattern DMP and a guard ring pattern GRP which is adjacent to the dummy pattern DMP, each disposed inside the base substrate BS and overlapping the pad area PDA. Specifically, the guard ring pattern GRP may be located between the dummy pattern DMP and the signal pads SPD in the plan view. For example, the dummy pattern DMP and guard ring pattern GRP may include a metal material. In an embodiment, the guard ring pattern GRP and the dummy pattern DMP may be in a same layer as components of the pixel circuit layer (e.g., the pixel circuit portions PXC.)

For example, the guard ring pattern GRP may have a shape which surrounds at least a part of a display area (e.g., the display area DA of FIG. 1) in a plan view.

A ground voltage may be applied to the dummy pattern DMP. In addition, the guard ring pattern GRP disperses electrostatic discharge flowing into the layered structure of the display panel DP from the outside thereof, thereby preventing defects in the display device DD due to electrostatic discharge. In an embodiment, the display device DD further includes the dummy pattern DMP which is inside the silicon substrate in the non-display area NDA and receives a ground voltage, and an electrostatic discharging pattern (e.g., the guard ring pattern GRP) which is inside the silicon substrate and adjacent to the dummy pattern DMP.

In an embodiment, the shielding layer SHL may be connected (e.g., electrically) to the dummy pattern DMP or the guard ring pattern GRP. Accordingly, electrostatic discharge flowing into the shielding layer SHL from the outside may be induced into the dummy pattern DMP or the guard ring pattern GRP. Accordingly, defects in the display device DD due to electrostatic discharge flowing into from the outside of the display panel DP or electrical elements thereof may be prevented. However, embodiments of the present disclosure are not limited thereto.

In embodiment, since the shielding layer SHL is in a different layer from the dummy pattern DMP and the guard ring pattern GRP, the shielding layer SHL may be connected (e.g., electrically) to the dummy pattern DMP or the guard ring pattern GRP at a contact hole defined in the insulating layer IL similar to how the light emitting element layer is connected to the pixel circuit layer at various contact holes described above. In this case, a part of the shielding layer SHL may extend to fill the contact hole. However, embodiments of the present disclosure are not limited thereto. In an embodiment, the shielding layer SHL may be connected (e.g., electrically) to the dummy pattern DMP or the guard ring pattern GRP via another element disposed at a location between the shielding layer SHL and a respective pattern among the dummy pattern DMP or the guard ring pattern GRP. As an example, such location may be defined within the sub-area SA illustrated in FIG. 1.

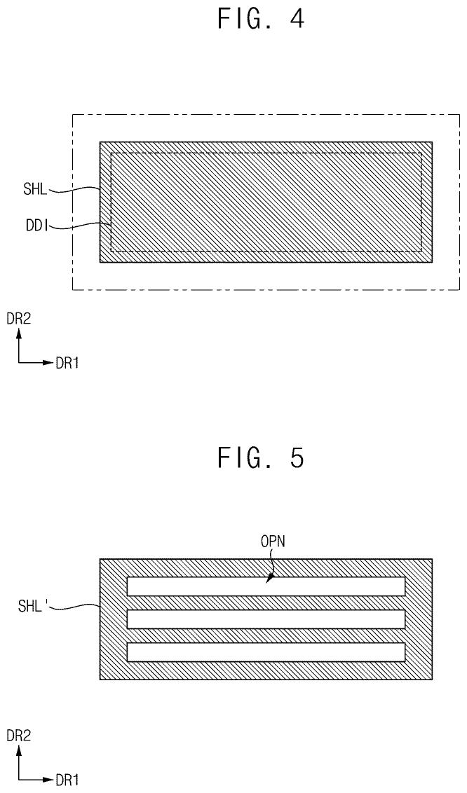

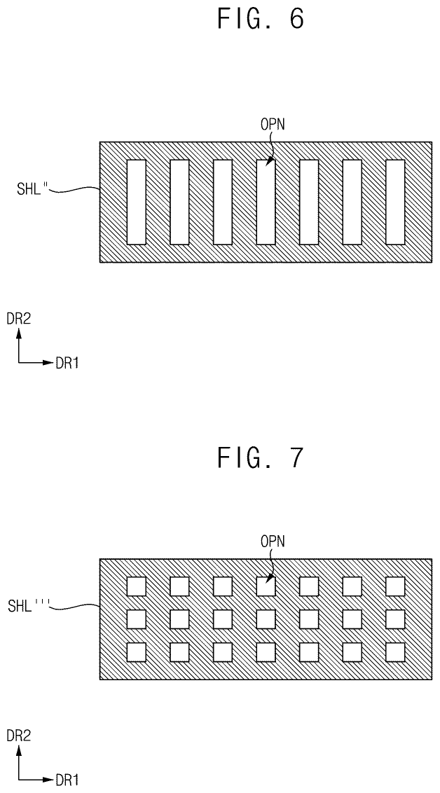

FIG. 4 is a plan view illustrating a driving circuit and a shielding layer of FIG. 3. FIGS. 5, 6, and 7 are plan views illustrating examples of the planar shape of a shielding layer of FIG. 3. Each of the shielding layer SHL and the driving circuit portion DDI has a planar shape and a planar area. An entirety of the planar shape (or the planar area) of the driving circuit portion DDI may be within the planar shape (or the planar area) of the shielding layer SHL.

Referring to FIG. 4, the shielding layer SHL as an electrostatic shielding layer may have various planar shapes. In an embodiment, the shielding layer SHL may have a quadrangular planar shape. For example, the shielding layer SHL may have a rectangular shape. Here, the shielding layer SHL may be a unitary body.

Referring to FIGS. 5 to 7, in an embodiment, the shielding layers SHL′, SHL″, and SHL″ may have a planar shape in which a plurality of openings OPN spaced apart from each other are defined.

In an embodiment, an opening OPN may extended completely through a thickness of the shielding layers SHL′, SHL″, and SHL″, such as to be open at both upper and lower surfaces thereof, without being limited thereto. Here, referring to FIGS. 5 to 7, with FIG. 3, the insulating layer IL may be exposed to outside the shielding layers SHL′, SHL″, and SHL″, at the various openings OPN defined extended through the thickness of the shielding layers SHL′, SHL″, and SHL′″. In an embodiment, an opening OPN may be extended through a partial thickness of the shielding layers SHL′, SHL″, and SHL″ such as to be recessed from (and open at) an upper surface and/or a lower surface of the shielding layers SHL′, SHL″, and SHL″. The openings OPN may be considered as discrete shapes defined within a solid portion of the various shielding layers SHL′, SHL″, and SHL″.

For example, as shown in FIG. 5, each of the openings OPN may extend to have a major planar direction in the first direction DR1, and the openings OPN may be arranged separated from each other along the second direction DR2. That is, a long side of each of the openings OPN which defines the major planar direction may extend in the first direction DR1.

Alternatively, as shown in FIG. 6, each of the openings OPN may extend to have a major planar in the second direction DR2 and the openings OPN may be arranged spaced apart from each other along the first direction DR1. That is, the long side of each of the openings OPN which defines the major planar dimension may extend in the second direction DR2.

Alternatively, as shown in FIG. 7, the openings OPN may be arranged in a matrix form along the first direction DR1 and the second direction DR2, spaced apart from each other in both directions by a solid portion of the shielding layer SH″ “.

However, the embodiments of the present disclosure are not limited to this, and the shielding layers SHL, SHL′, SHL”, and SHL″ may have a planar shape different from the planar shape shown in FIGS. 4, 5, 6, and 7.

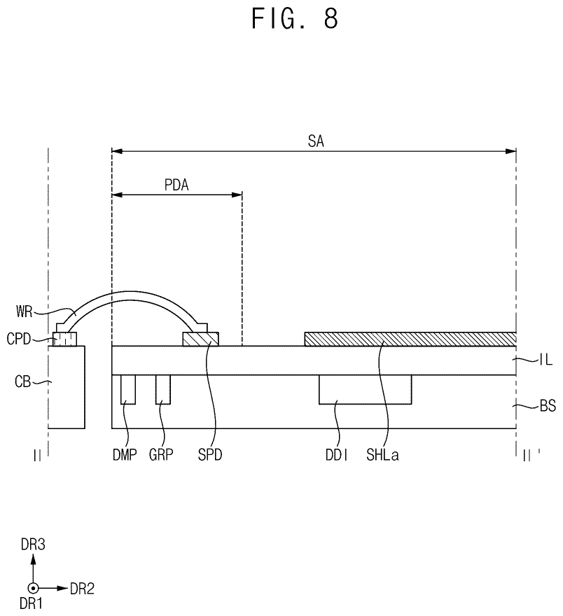

FIG. 8 is a cross-sectional view illustrating an example of a cross-section taken along line II-II′ in FIG. 1. Hereinafter, content which overlaps with the content described with reference to FIG. 3 will be omitted or simplified.

Referring to FIGS. 1, 2, and 8, a shielding layer SHLa may be disposed on the insulating layer IL and may cover the driving circuit portion DDI in the plan view. Specifically, the shielding layer SHLa may cover the entire driving circuit portion DDI in the plan view. For example, the shielding layer SHLa may include a metal material. In an embodiment, the shielding layer SHLa may include the same material as the common electrode CE of FIG. 2. That is, the shielding layer SHLa may be formed through the same process as the common electrode CE of FIG. 2.

The common electrode CE of FIG. 2 may continuously extend from the display area DA to at least a part of the non-display area NDA (e.g., at least a part of the sub-area SA), to define an extended portion of the common electrode CE which is in the non-display area NDA. The extended portion may extend to the driving circuit portion DDI. In an embodiment, the shielding layer SHLa may include a part of the common electrode CE of FIG. 2 which overlaps the non-display area NDA (e.g., the sub-area SA). That is, the shielding layer SHLa may be electrically and/or physically connected to the common electrode CE of FIG. 2 in a direction along the insulating layer IL, as illustrated by the shielding layer SHLa meeting the (right) broken line indicating the sub-area SA.

In an embodiment, the shielding layer SHLa may be connected to the dummy pattern DMP or the guard ring pattern GRP. Accordingly, electrostatic discharge flowing into the shielding layer SHLa from the outside may be induced into the dummy pattern DMP or the guard ring pattern GRP. Accordingly, defects in the display device DD due to electrostatic discharge flowing into from the outside may be prevented. However, embodiments of the present disclosure are not limited thereto.

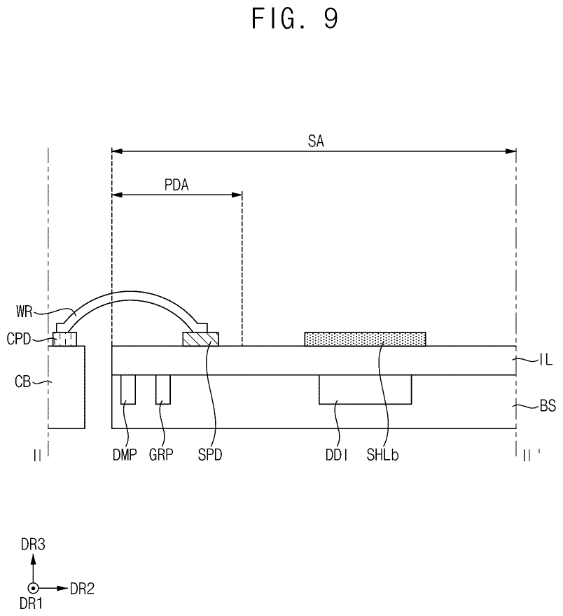

FIG. 9 is a cross-sectional view illustrating an example of a cross-section taken along line II-II′ in FIG. 1. Hereinafter, content which overlaps with the content described with reference to FIG. 3 will be omitted or simplified.

Referring to FIGS. 1, 2, and 9, a shielding layer SHLb may be disposed on the insulating layer IL and may cover the driving circuit portion DDI in the plan view. Specifically, the shielding layer SHLb may cover the entire driving circuit portion DDI in the plan view. For example, the shielding layer SHLb may include a metal material. In an embodiment, the shielding layer SHLb may include the same material as the first, second, and third pixel electrodes PE1, PE2, and PE3 of FIG. 2. That is, the shielding layer SHLb may be formed through the same process as the first, second, and third pixel electrodes PE1, PE2, and PE3 of FIG. 2.

In an embodiment, the shielding layer SHLb may be spaced apart from the first, second, and third pixel electrodes PE1, PE2, and PE3 of FIG. 2. That is, the shielding layer SHLb may not be connected to the first, second, and third pixel electrodes PE1, PE2, and PE3 of FIG. 2 in a direction along the insulating layer IL, as illustrated by the shielding layer SHLb spaced apart from the (right) broken line indicating the sub-area SA (e.g., electrically and/or physically disconnected therefrom). However, embodiments of the present disclosure are not limited to this, and the shielding layer SHLb may be connected to the first, second, and third pixel electrodes PE1, PE2, and PE3 of FIG. 2 in a direction along the insulating layer IL, similar to that illustrated by the shielding layer SHLa meeting the (right) broken line indicating a the sub-area SA.

In an embodiment, the shielding layer SHLb may be connected to the dummy pattern DMP or the guard ring pattern GRP. Accordingly, electrostatic discharge flowing into the shielding layer SHLb from the outside may be induced into the dummy pattern DMP or the guard ring pattern GRP. Accordingly, defects in the display device DD due to electrostatic discharge flowing into from the outside may be prevented. However, embodiments of the present disclosure are not limited thereto.

The shielding layer SHLb may have various planar shapes. For example, the shielding layer SHLb may have the same planar shape as any one of the shielding layers SHL, SHL′, SHL″, and SHL″ of FIGS. 4, 5, 6, and 7. However, embodiments of the present disclosure are not limited thereto.

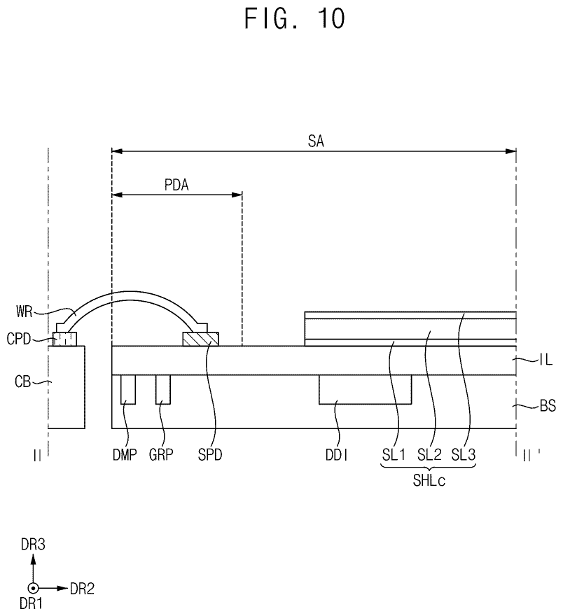

FIG. 10 is a cross-sectional view illustrating an example of a cross-section taken along line II-II′ in FIG. 1. Hereinafter, content which overlaps with the content described with reference to FIG. 3 will be omitted or simplified.

Referring to FIGS. 1, 2, and 10, a shielding layer SHLc may be disposed on the insulating layer IL and may cover the driving circuit portion DDI in the plan view. Specifically, the shielding layer SHLc may cover the entire driving circuit portion DDI in the plan view. For example, the shielding layer SHLc may include an inorganic material. In an embodiment, the shielding layer SHLc may include one or more of the same materials as the encapsulation layer TFE of FIG. 2. That is, the shielding layer SHLc may be formed through the same process as one or more material layer of the encapsulation layer TFE of FIG. 2.

Accordingly, the shielding layer SHLc may also have the same laminated structure as the encapsulation layer TFE. That is, the shielding layer SHLc may include a first sub-layer SL1 and including an inorganic material, a second sub-layer SL2 disposed the first sub-layer SL1 and including an organic material, and a third sub-layer SL3 disposed the second sub-layer SL2 and including an inorganic material. The first sub-layer SL1 may include the same material as the first inorganic encapsulation layer TFE1 of FIG. 2, the second sub-layer SL2 may include the same material as the organic encapsulation layer TFE2 of FIG. 2, and the third sub-layer SL3 may include the same material as the second inorganic encapsulation layer TFE3 of FIG. 2.

The encapsulation layer TFE of FIG. 2 may continuously extend from the display area DA to at least a part of the non-display area NDA (e.g., at least a part of the sub-area SA). In an embodiment, the shielding layer SHLc may include a part and/or a pattern of the encapsulation layer TFE of FIG. 2 which overlaps the non-display area NDA (e.g., the sub-area SA). That is, the shielding layer SHLc may be connected to the encapsulation layer TFE of FIG. 2 in a direction along the insulating layer IL, as illustrated by the shielding layer SHLc meeting the (right) broken line indicating the sub-area SA.

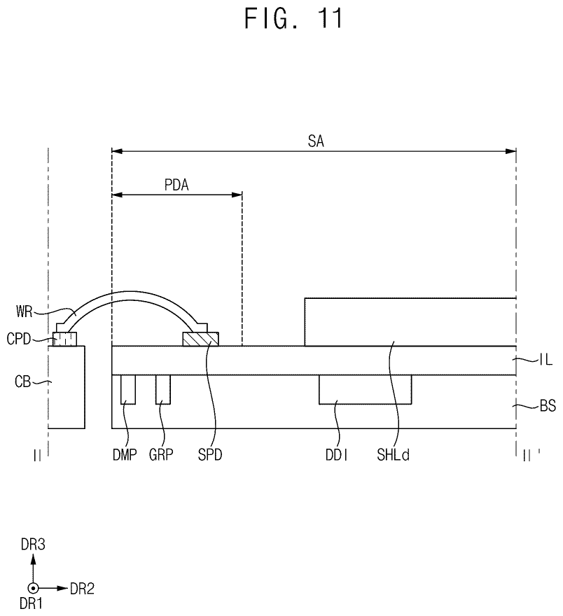

FIG. 11 is a cross-sectional view illustrating an example of a cross-section taken along line II-II′ in FIG. 1. Hereinafter, content which overlaps with the content described with reference to FIG. 3 will be omitted or simplified.

Referring to FIGS. 1, 2, and 11, a shielding layer SHLd may be disposed on the insulating layer IL and may cover the driving circuit portion DDI in the plan view. Specifically, the shielding layer SHLd may cover the entire driving circuit portion DDI in the plan view. For example, the shielding layer SHLd may include glass. In an embodiment, the shielding layer SHLd may include the same material as the encapsulation substrate ES of FIG. 2.

The encapsulation substrate ES of FIG. 2 may continuously extend from the display area DA to at least a part of the non-display area NDA (e.g., at least a part of the sub-area SA). In an embodiment, the shielding layer SHLd may include a part of the encapsulation substrate ES of FIG. 2 overlapping the non-display area NDA (e.g., the sub-area SA). That is, the shielding layer SHLd may be connected to the encapsulation substrate ES of FIG. 2 in a direction along the insulating layer IL, as illustrated by the shielding layer SHLd meeting the (right) broken line indicating the sub-area SA.

Referring again to FIGS. 1, 2, 3, 4, 5, 6, 7, 8, 9, 10, and 11, the display device DD according to embodiments of the present disclosure may include the base substrate BS including a silicon wafer, the driving circuit portion DDI disposed inside the base substrate BS in the non-display area NDA (e.g., the sub-area SA), and a shielding layer SHL disposed on the driving circuit portion DDI and covering the entire driving circuit portion DDI in the plan view. The shielding layer may correspond to any one of the shielding layers SHL, SHL′, SHL″, SHL″, SHLa, SHLb, SHLc, and SHLd of FIGS. 3, 4, 5, 6, 7, 8, 9, 10, and 11. Accordingly, the shielding layer SHL may block or prevent external electrostatic discharge from flowing into the driving circuit portion DDI. In this case, defects in the display device DD due to electrostatic discharge may be prevented.

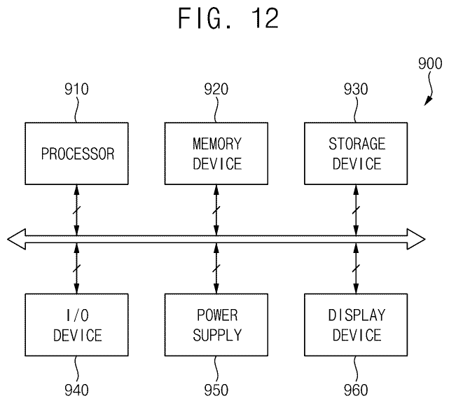

FIG. 12 is a block diagram illustrating an electronic device according to an embodiment of the present disclosure.

Referring to FIG. 12, in an embodiment, an electronic device 900 may include a processor 910, a memory device 920, a storage device 930, an input/output device 940, a power supply 950, and a display device 960. In this case, the display device 960 may correspond to the display device DD described with reference to FIGS. 1 to 11. The electronic device 900 may further include several ports capable of communicating with a video card, a sound card, a memory card, a USB device, and the like.

In an embodiment, the electronic device 900 may be implemented as a television. In another embodiment, the electronic device 900 may be implemented as a smart phone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and the like.

The processor 910 may perform certain calculations or tasks. The processor 910 may control the display device 960. In an embodiment, the processor 910 may be a microprocessor, a central processing unit (CPU), an application processor (AP), and/or the like. The processor 910 may be connected to other components through an address bus, a control bus, a data bus, and the like. The processor 910 may also be connected to an expansion bus, such as a peripheral component interconnect (PCI) bus.

The memory device 920 may store data necessary for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 930 may include a solid state drive (SSD), a hard disk drive (HDD), a CD-ROM, and the like.

The input/output device 940 may include input means such as a keyboard, keypad, touch pad, touch screen, mouse, and the like and output means such as a speaker, a printer, and the like.

The power supply 950 may supply power necessary for the operation of the electronic device 900. The display device 960 may be connected to other components through buses or other communication links. In an embodiment, the display device 960 may be included in the input/output device 940.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a silicon substrate including:
a display area including a light emitting element, and a pixel circuit portion which is inside the silicon substrate and connected to the light emitting element, and
a non-display area which is adjacent to the display area, the non-display area including:
a driving circuit portion which is inside the silicon substrate and through which an electrical signal is provided to the display area; and
an electrostatic shielding layer covering the driving circuit portion.

2. The display device of claim 1, wherein the electrostatic shielding layer includes a metal material.

3. The display device of claim 1, wherein the light emitting element comprises:
a pixel electrode on the silicon substrate;
a light emitting layer on the pixel electrode; and
a common electrode on the light emitting layer.

4. The display device of claim 3, wherein the electrostatic shielding layer and the common electrode are respective patterns of a same material layer.

5. The display device of claim 4, wherein the electrostatic shielding layer is spaced apart from the common electrode.

6. The display device of claim 4, wherein
the common electrode continuously extends from the display area to the non-display area, and
the electrostatic shielding layer is defined by a portion of the common electrode which is in the non-display area.

7. The display device of claim 3, wherein the electrostatic shielding layer and the pixel electrode are respective patterns of a same material layer.

8. The display device of claim 7, wherein the electrostatic shielding layer is spaced apart from the pixel electrode.

9. The display device of claim 1, wherein the electrostatic shielding layer includes an inorganic material.

10. The display device of claim 1, wherein the electrostatic shielding layer includes glass.

11. The display device of claim 1, further comprising:
an encapsulation layer on the light emitting element and including an inorganic layer and an organic layer; and
an encapsulation substrate facing the encapsulation layer and including glass.

12. The display device of claim 11, wherein the electrostatic shielding layer and the encapsulation layer are respective patterns of a same material layer.

13. The display device of claim 11, wherein the electrostatic shielding layer and the encapsulation substrate are respective patterns of a same material layer.

14. The display device of claim 1, further comprising in the non-display area:
a dummy pattern which is inside the silicon substrate in the non-display area and receives a ground voltage; and
an electrostatic discharging pattern which is inside the silicon substrate and adjacent to the dummy pattern.

15. The display device of claim 14, wherein the electrostatic shielding layer is connected to the dummy pattern or to the electrostatic discharging pattern.

16. The display device of claim 1, wherein the electrostatic shielding layer has a planar shape in which openings are defined spaced apart from each other.

17. A display device comprising:
a silicon substrate including:
a display area including a light emitting element, and a pixel circuit portion which is inside the silicon substrate and connected to the light emitting element, and
a non-display area which is adjacent to the display area, the non-display area including:
a pad area spaced apart from the display area in a first direction;
a driving circuit portion which is inside the silicon substrate in an area of the non-display area which excludes the pad area;
an electrostatic shielding layer covering the driving circuit portion; and
signal pads arranged in the pad area, along a second direction crossing the first direction;
a circuit board which is electrically connected to the silicon substrate at the signal pads of the pad area; and
a timing controller which is directly on the circuit board.

18. The display device of claim 17, wherein
the light emitting element comprises:
a pixel electrode on the silicon substrate;
a light emitting layer on the pixel electrode; and
a common electrode on the light emitting layer; and
the electrostatic shielding layer and the pixel electrode are respective patterns of a same material layer or the electrostatic shielding layer and the common electrode are respective patterns of a same material layer.

19. The display device of claim 17, further comprising:
an encapsulation layer on the light emitting element and including an inorganic layer and an organic layer; and
an encapsulation substrate facing the encapsulation layer and including glass,
wherein the electrostatic shielding layer and the encapsulation layer are respective patterns of a same material layer or the electrostatic shielding layer and the encapsulation substrate are respective patterns of a same material layer.

20. The display device of claim 17, further comprising:
in the non-display area:
a dummy pattern which is inside the silicon substrate and receives a ground voltage; and
an electrostatic discharging pattern which is inside the silicon substrate and adjacent to the dummy pattern; and
the electrostatic shielding layer connected to the dummy pattern or the electrostatic discharging pattern.

21. An electronic device comprising:
a display device; and
a processor which controls the display device,
wherein the display device includes:
a silicon substrate including:
a display area including a light emitting element, and a pixel circuit portion which is inside the silicon substrate and connected to the light emitting element, and
a non-display area which is adjacent to the display area, the non-display area including:
a driving circuit portion which is inside the silicon substrate and through which an electrical signal is provided to the display area; and
an electrostatic shielding layer covering the driving circuit portion.
